(19) United States
(12) Patent Application Publication
(10) Pub. No.: US 2024/0053280 A1
(43) Pub. Date: Feb. 15, 2024

(54) Methods And Systems For Systematic Error Compensation Across A Fleet Of Metrology Systems Based On A Trained Error Evaluation Model

(71) Applicant: KLA Corporation, Milpitas, CA (US)

(72) Inventors: Ming Di, Pleasanton, CA (US); Yih-Chung Chang, Davis, CA (US); Xi Chen, Fremont, CA (US); Dawei Hu, Milpitas, CA (US); Ce Xu, Shanghai (CN); Bowei Huang, Hsinchu City (TW); Igor Baskin, San Jose, CA (US); Mark Allen Neil, San Jose, CA (US); Tianhao Zhang, Livermore, CA (US); Malik Karman Sadiq, Walnut Creek, CA (US); Shankar Krishnan, Cupertino, CA (US); Jenching Tsai, Hsinchu City (TW); Carlos L. Ygartua, San Jose, CA (US); Yao-Chung Tsao, Hsinchu County (TW); Qiang Zhao, Milpitas, CA (US)

(21) Appl. No.: 18/229,606

(22) Filed: Aug. 2, 2023

Related U.S. Application Data
(60) Provisional application No. 63/396,240, filed on Aug. 9, 2022.

(51) Int. Cl. G01N 21/95; H01L 21/66

(52) U.S. Cl. CPC G01N 21/9501; H01L 22/12

(57) ABSTRACT

Methods and systems for compensating systematic errors across a fleet of metrology systems based on a trained error evaluation model to improve matching of measurement results across the fleet are described herein. In one aspect, the error evaluation model is a machine learning based model trained based on a set of composite measurement matching signals. Composite measurement matching signals are generated based on measurement signals generated by each target measurement system and corresponding model-based measurement signals associated with each target measurement system and reference measurement system. The training data set also includes an indication of whether each target system is operating within specification, an indication of the values of system model parameter of each target system, or both. In some embodiments, the composite measurement matching signals driving the training of the error evaluation model are weighted differently, for example, based on measurement sensitivity, measurement noise, or both.

### CROSS REFERENCE TO RELATED APPLICATION

The present application for patent claims priority under 35 U.S.C. § 119 from U.S. provisional patent application Ser. No. 63/396,240, entitled “Matching Harmonics Generation of Nanosheet logic, DRAM, and 3D-Flash for Systematic Error Optimization between Ellipsometry Optical Metrology Systems by General Machine Learning,” filed Aug. 9, 2022, the subject matter of which is incorporated herein by reference in its entirety.

### TECHNICAL FIELD

The described embodiments relate to metrology systems and methods, and more particularly to methods and systems for improved measurement of parameters characterizing semiconductor structures.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical metrology techniques offer the potential for high throughput measurement without the risk of sample destruction. A number of optical metrology based techniques including scatterometry, reflectometry, and ellipsometry implementations and associated analysis algorithms are commonly used to characterize critical dimensions, film thicknesses, composition and other parameters of nanoscale structures.

In general, the semiconductor industry strives to produce ever smaller devices with increasing structural complexity and material types. Exemplary devices that exhibit such complexity include Gate-All-Around (GAA) Field Effect Transistors (FET), current Dynamic Random Access Memory (DRAM) structures, and current three dimensional flash memory structures.

In one example, GAA FETs manufactured using nanosheet fabrication techniques enable improved device performance and low power consumption, but are difficult to manufacture due to their nanoscale size and complex shape. Nanosheet structures include several material layers. The process of fabricating a nanosheet structure starts by growing a superlattice of Silicon and Silicon Germanium layers. These layers comprise the base structure of a nanosheet. It is critical to measure the characteristics of each layer, e.g., film thickness, to maintain control of the manufacturing process.

In another example, flash memory architectures are transitioning from two dimensional floating-gate architectures to fully three dimensional geometries. In some examples, film stacks and etched structures are very deep (e.g., three or more micrometers in depth) and include an extremely high number of layers (e.g., 400 layers, or more). High aspect ratio structures create challenges for film and CD measurements. The ability to measure the critical dimensions that define the shapes of holes and trenches of these structures is critical to achieve desired performance levels and device yield. The metrology must be capable of measuring the CD of a continuous profile through a deep channel to determine the location of CD variations and inflection points of profile variations.

As devices (e.g., logic and memory devices) move toward smaller nanometer-scale dimensions, characterization becomes more difficult. Devices incorporating complex three-dimensional geometry and materials with diverse physical properties contribute to characterization difficulty. In addition to accurate device characterization, measurement consistency across a range of measurement applications and a fleet of metrology systems tasked with the same measurement objective is also important. If measurement consistency degrades in a manufacturing environment, consistency among processed semiconductor wafers is lost and yield drops to unacceptable levels. Matching measurement results across applications and across multiple systems (i.e., tool-to-tool matching) ensures that measurement results on the same wafer for the same application yield the same result.

A typical calibration approach for model based measurement systems consists of measuring a number of film/substrate systems of known thickness and dielectric function. A regression is performed on machine parameters until the combination of parameters returns the expected values for thickness and/or dielectric function. In one example, a set of film wafers having a silicon dioxide layer on crystalline silicon over a range of thicknesses is measured and a regression is performed on the machine parameters until the machine returns the best match for thickness and/or refraction index for the given set of films. Other examples are described in U.S. Pat. Pub. No. 2004/0073398 entitled, “Methods and Systems for Determining a Critical Dimension and a Thin Film Characteristic of a Specimen,” which is incorporated by reference as if fully set forth herein. This calibration procedure may be applied across a fleet of measurement systems using the same set of wafers. These wafers are sometimes referred to as transfer standards.

Calibration of a fleet of measurement systems using a transfer standard suffers from a number of disadvantages. To obtain high accuracy results, calibration experiments involving the reference wafer must be performed in a carefully controlled environment that matches the environmental conditions in place when the reference wafer was originally characterized. This may be difficult to achieve in a manufacturing environment and lead to loss of consistency among measurement systems. In addition, an expensive reference wafer set must be maintained in the manufacturing environment. Risks of wafer breakage or degradation potentially jeopardize the integrity of the calibration process, and the risks increase when the metrology systems to be calibrated are located in different fabrication facilities.

Machine parameters are often calibrated based on thin film measurements because thin film systems (e.g., silicon dioxide on crystalline silicon) can be manufactured with well-known optical constants, clean interfaces, and low surface roughness that enable measurement of wafer characteristics with a degree of repeatability near the sensitivity of the measurement systems being calibrated. However, the accuracy of a metrology system calibrated based on reference wafers is typically limited to wafers with properties that closely match those of the reference wafer. Thus, the effectiveness of calibration based on thin film measurements may be limited in different measurement applications.

In another approach, system parameter calibration to achieve measurement consistency over time and over different measurement applications is improved by matching measurement spectra across a fleet of metrology systems, rather than specimen parameter values. System parameter values are optimized such that differences between measured spectra generated by a reference system and a target system are minimized for measurements of the same metrology targets. The updated system parameter values are employed in subsequent measurement analyses performed by the target metrology system (e.g., CD measurements, thin-film measurements, CD matching applications, etc.). Further description of this approach is described in U.S. Pat. Nos. 9,857,291 and 10,605,722 assigned to KLA-Tencor Corporation, the contents of each are incorporated herein by reference in their entirety.

In yet another approach, system parameter calibration to achieve measurement consistency over time and over different measurement applications is improved by matching spectral errors across a fleet of metrology systems. System parameter values of a target metrology system are calibrated based on spectral error matching with a reference metrology system. In this approach, the spectral error is difference between the measured spectra and a modeled spectral response of the specimen under measurement. One or more system parameters of a target metrology system are calibrated to minimize the difference between the spectral error associated with the measurement of one or more metrology targets measured by a reference metrology system and the spectral error associated with the measurement of the same metrology targets measured by the target metrology system. Further description of this approach is described in U.S. Pat. No. 10,006,865 assigned to KLA-Tencor Corporation, the content of which is incorporated herein by reference in its entirety.

Matching spectral errors across a fleet of metrology systems with respect to a reference metrology system, e.g., a “golden” tool, introduces some limitations. For example, all the target metrology systems of the fleet must be recalibrated to maintain systematic errors within the desired tolerance when the reference metrology system undergoes hardware changes or maintenance operations. In another example, spectral error data loses significant signal information specific to the measured metrology target because the data is based on the difference between measured and theoretical signal, rather than the measured signals themselves. In another example, system parameter optimization that minimizes spectral errors is complex and computationally burdensome.

Tool-to-tool matching and maintaining tool measurement consistency over time, over maintenance cycles, and over a wide range of measurement applications are core challenges in the development of a metrology system that meets customer requirements of the semi-conductor industry. Process and yield control in both the research and development and manufacturing environments demands tool-to-tool consistency of measurement results on the order of the measurement repeatability. Thus, methods and systems for improved tool-to-tool matching and consistent measurement performance over a wide range of measurement applications are desired.

### SUMMARY

Methods and systems for compensating systematic errors across a fleet of metrology systems based on a trained error evaluation model are described herein. Compensation of systematic errors improves matching of measurement results across the fleet of metrology systems over a range of metrology targets and measurement applications.

In one aspect, the error evaluation model is a machine learning based model trained based on a set of composite measurement matching signals. Composite measurement matching signals are generated based on measurement signals generated by each target system and corresponding model-based measurement signals associated with each target measurement system and a reference measurement system. The trained error evaluation model enables rapid systematic error monitoring and optimization across large numbers of metrology tools. The trained error evaluation model enables optimization of system parameters among a fleet of metrology tools without simulation of measurement system model parameters. Thus, computational effort is dramatically reduced.

The composite measurement matching signals associated with each metrology tool incorporate measurement information specific to each target metrology tool, reference metrology tool, and metrology target with reduced complexity compared to traditional tool matching approaches. For purposes of error monitoring across a fleet of metrology tools, an indication of whether each target system is operating within specification is included as part of the training data set. For purposes of system parameter optimization across a fleet of metrology tools, the system model parameters of each target system employed to provide measurement data is included as part of the training data set.

In a further aspect, optimized system parameters are subsequently used for further measurement analyses. In some examples, critical dimension (CD) measurements are performed by the target measurement system using the optimized subset of system parameters. For example, a structural parameter of a metrology target may be estimated based on a regression of the updated target system measurement model on the spectral data associated with the measurement of the metrology target.

In another further aspect, the composite measurement matching signals driving the training of the error evaluation model may be weighted differently. In one example, the relative weightings are based on measurement sensitivity to any of multiple measurement sites, multiple measurement samples, multiple illumination wavelengths, and multiple measurement subsystems. In this manner, specific measurement sites, samples, subsystems, or illumination wavelengths with particularly high measurement sensitivity are emphasized. In another example, the relative weightings are based on measurement noise associated any of multiple measurement sites, multiple measurement samples, multiple illumination wavelengths, and multiple measurement subsystems. In this manner, specific measurement sites, samples, subsystems, or illumination wavelengths with particularly high measurement noise are de-emphasized.

The foregoing is a summary and thus contains, by necessity, simplifications, generalizations, and omissions of detail. Consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a simplified diagram illustrative of a metrology system 100 operable in accordance with the methods for systematic error monitoring and correction across a fleet of metrology systems as described herein.

FIG. 2 is a diagram illustrative of an error evaluation model based fleet matching engine in one embodiment.

FIG. 3 is a diagram illustrative of an error evaluation model training engine in one embodiment.

FIGS. 4A-B are plots illustrative of matching of spectral measurement signals between a target metrology system and a reference metrology system over a range of illumination wavelengths before and after calibration of target system parameters using a trained error evaluation model.

FIG. 5 is a flowchart illustrative of a method for systematic error monitoring across a fleet of metrology systems as described herein.

### DETAILED DESCRIPTION

Reference will now be made in detail to background examples and some embodiments of the invention, examples of which are illustrated in the accompanying drawings.

Methods and systems for compensating systematic errors across a fleet of metrology systems based on a trained error evaluation model are described herein. The trained error evaluation model enables rapid systematic error monitoring and optimization across large numbers of metrology tools. Compensation of systematic errors improves matching of measurement results across the fleet of metrology systems over a range of metrology targets and measurement applications. The trained error evaluation model enables optimization of system parameters among a fleet of metrology tools without simulation of measurement system model parameters. Thus, computational effort is dramatically reduced.

In one aspect, the error evaluation model is a machine learning based model trained based on a set of composite measurement matching signals. Composite measurement matching signals are generated based on measurement signals generated by each target system and corresponding model-based measurement signals associated with each target measurement system and a reference measurement system. For each target metrology system, a composite measurement matching signal associated with a particular metrology target is a mathematical function of 1) actual measurements signals generated based on a measurement of the metrology target by the target measurement system; 2) a model-based measurement signal predicted by a model of the measurement of the metrology target by the target measurement system; and 3) a model-based measurement signal predicted by a model of a measurement of the metrology target by a reference metrology system.

The composite measurement matching signals associated with each metrology tool incorporate measurement information specific to each target metrology tool, reference metrology tool, and metrology target with reduced complexity compared to traditional tool matching approaches. For purposes of error monitoring across a fleet of metrology tools, an indication of whether each target system is operating within specification is included as part of the training data set. For purposes of system parameter optimization across a fleet of metrology tools, the system model parameters of each target system employed to provide measurement data is included as part of the training data set.

Metrology targets employed to train a machine learning based error evaluation model include, but not limited to nanosheet logic structures, DRAM structures, 3D Flash memory structures, etc. Fleets of metrology systems matched using a trained machine learning based error evaluation model are employed to measure structural and material characteristics (e.g., material composition, dimensional characteristics of structures and films, etc.) associated with different semiconductor fabrication processes.

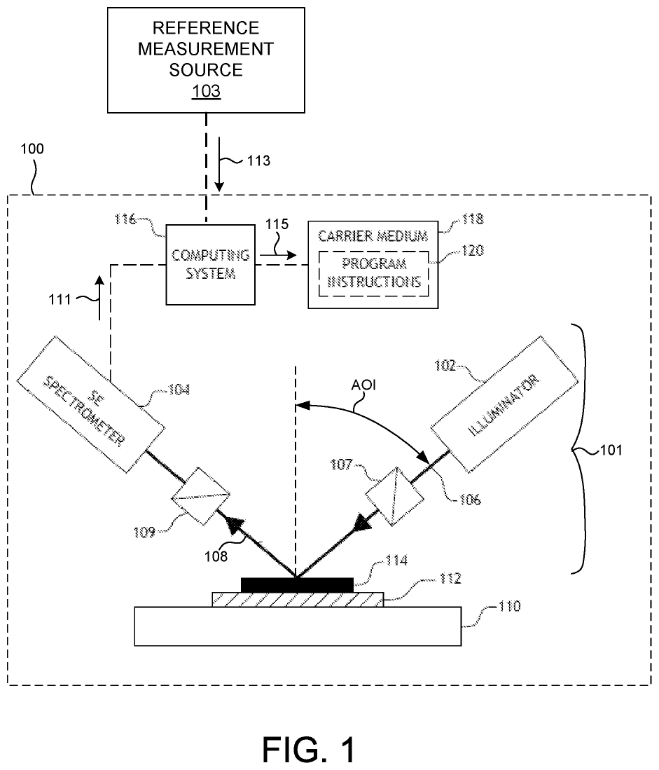

FIG. 1 illustrates a metrology system 100 for measuring characteristics of a semiconductor wafer in accordance with the exemplary methods presented herein. As shown in FIG. 1, the system 100 may be used to perform spectroscopic ellipsometry measurements of one or more structures 114 of a semiconductor wafer 112 disposed on a wafer positioning system 110. In this aspect, the system 100 may include a spectroscopic ellipsometer (SE) 101 equipped with an illuminator 102 and a spectrometer 104. The illuminator 102 of the system 100 is configured to generate and direct illumination of a selected wavelength range (e.g., 150-850 nm, 190-850 nm, 240-850 nm, etc.) to the structure 114 disposed on the surface of the semiconductor wafer 112. In turn, the spectrometer 104 is configured to receive illumination reflected from the surface of the semiconductor wafer 112. It is further noted that the light emerging from the illuminator 102 is polarized using a polarization state generator 107 to produce a polarized illumination beam 106. The radiation reflected by the structure 114 disposed on the wafer 112 is passed through a polarization state analyzer 109 and to the spectrometer 104. The radiation received by the spectrometer 104 in the collection beam 108 is analyzed with regard to polarization state, allowing for spectral analysis by the spectrometer of radiation passed by the analyzer. These spectra 111 are passed to the computing system 116 for analysis of the structure 114.

In a further embodiment, metrology system 100 is a target measurement system 100 that may include one or more computing systems 116 employed to perform calibration of the system parameter values of the target measurement system 100 in accordance with the methods described herein. The one or more computing systems 116 may be communicatively coupled to the spectrometer 104. In one aspect, the one or more computing systems 116 are configured to receive measurement data 111 associated with a measurement of the structure 114 of specimen 112. In one example, the measurement data 111 includes an indication of the measured spectral response of the specimen by target measurement system 100 based on the one or more sampling processes from the spectrometer 104.

In addition, in some embodiments, the one or more computing systems 116 are further configured to receive model based measurement data 113 from a reference measurement source 103. In one example, the model based measurement data 113 includes simulated spectra associated with a measurement of the structure 114 by a reference metrology system. In some examples, the set of parameter values is stored in carrier medium 118 and retrieved by computing system 116.

It should be recognized that the various elements described throughout the present disclosure may be carried out by a single computer system 116 or, alternatively, a multiple computer system 116. Moreover, different subsystems of the system 100, such as the spectroscopic ellipsometer 101, may include a computer system suitable for carrying out at least a portion of the steps described herein. Therefore, the aforementioned description should not be interpreted as a limitation on the present invention but merely an illustration. Further, the one or more computing systems 116 may be configured to perform any other step(s) of any of the method embodiments described herein. Moreover, some or all of the one or more computing systems 116 may be located remotely from the site of wafer measurement. For example, elements of computing system 116 configured to perform any of the methods described herein may be located at another facility remotely located from the site of where the wafer is measured.

In this regard, there is no requirement that spectral acquisition and subsequent analysis of the spectral data need be contemporaneous or performed in spatial proximity. For instance, spectral data may be stored in memory for analysis at a later time. In another instance, spectral results may be obtained and transmitted to a computing system located at a remote location for analysis.

In addition, the computer system 116 may be communicatively coupled to the spectrometer 104, the illuminator subsystem 102 of the ellipsometer 101, or the reference measurement source 103 (e.g., an external memory, a reference metrology system, etc.) in any manner known in the art. For example, the one or more computing systems 116 may be coupled to a computing system of the spectrometer 104 of the ellipsometer 101 and a computing system of the illuminator subsystem 102. In another example, the spectrometer 104 and the illuminator 102 may be controlled by a single computer system. In this manner, the computer system 116 of the system 100 may be coupled to a single ellipsometer computer system.

The computer system 116 of the system 100 may be configured to receive and/or acquire data or information from the subsystems of the system (e.g., spectrometer 104, illuminator 102, and the like) by a transmission medium that may include wireline and/or wireless portions. In this manner, the transmission medium may serve as a data link between the computer system 116 and other subsystems of the system 100. Further, the computing system 116 may be configured to receive measurement data via a storage medium (i.e., memory). For instance, the spectral results obtained using a spectrometer of ellipsometer 101 may be stored in a permanent or semi-permanent memory device (not shown). In this regard, the spectral results may be imported from an external system.

Moreover, the computer system 116 may send data to external systems via a transmission medium. The computer system 116 of the system 100 may be configured to receive and/or acquire data or information from other systems (e.g., inspection results from an inspection system or metrology results from a metrology system) by a transmission medium that may include wireline and/or wireless portions. In this manner, the transmission medium may serve as a data link between the computer system 116 and other subsystems of the system 100. Moreover, the computer system 116 may send data to external systems via a transmission medium.

The computing system 116 may include, but is not limited to, a personal computer system, cloud-based computer system, mainframe computer system, workstation, image computer, parallel processor, or any other device known in the art. In general, the term “computing system” may be broadly defined to encompass any device having one or more processors, which execute instructions from a memory medium.

Program instructions 120 implementing methods such as those described herein may be transmitted over or stored on carrier medium 118. The carrier medium may be a transmission medium such as a wire, cable, or wireless transmission link. The carrier medium may also include a computer-readable medium such as a read-only memory, a random access memory, a solid-state memory, a magnetic or optical disk, or a magnetic tape.

The embodiments of the system 100 illustrated in FIG. 1 may be further configured as described herein. In addition, the system 100 may be configured to perform any other block(s) of any of the method embodiment(s) described herein.

As illustrated in FIG. 1, a beam of broadband radiation from illuminator 102 is linearly polarized in polarization state generator 107, and the linearly polarized beam is then incident on specimen 112. After reflection from specimen 112, the beam propagates toward polarization state analyzer 109 with a changed polarization state. In some examples, the reflected beam has elliptical polarization. The reflected beam propagates through polarization state analyzer 109 into spectrometer 104. In spectrometer 104, the beam components having different wavelengths are refracted (e.g., in a prism spectrometer) or diffracted (e.g., in a grating spectrometer) in different directions to different detectors. The detectors may be a linear array of photodiodes, with each photodiode measuring radiation in a different wavelength range.

In one example, computing system 116 receives the measured data (e.g., raw measurement data) from each detector, and is programmed with software for processing the data it receives in an appropriate manner. The measured spectral response of a specimen may be determined by analyzing the changes in polarization of radiation reflected from the sample in response to incident radiation having known polarization state in any number of ways known in the art.

Any of polarization state generator 107 and polarization state analyzer 109 may be configured to rotate about their optical axis during a measurement operation. In some examples, computing system 116 is programmed to generate control signals to control the angular orientation of polarization state generator 107 and/or polarization state analyzer 109, or other elements of the system 100 (e.g., wafer positioning system 110 upon which specimen 112 rests). Computing system 116 may also receive data indicative of the angular orientation of polarization state analyzer 109 from an analyzer position sensor associated with polarization state analyzer 109. Similarly, computing system 116 may also receive data indicative of the angular orientation of polarization state generator 107 from a polarizer position sensor associated with polarization state generator 107. Computing system 116 may be programmed with software for processing such orientation data in an appropriate manner.

In one embodiment, the polarization state generator 107 is a linear polarizer that is controlled so that it rotates at a constant speed, and the polarization state analyzer is a linear polarizer that is not rotating (“the analyzer”). The signal received at each detector of spectrometer 104 (i.e., the raw measurement data) will be a time-varying intensity given by:

I(t)=I₀[1+α cos(2ωt−P₀)+β sin(2ωt−P₀))] (1)

where I₀ is a constant that depends on the intensity of radiation emitted by illuminator 102, ω is the angular velocity of polarization state generator 107, P₀ is the angle between the optical axis of polarization state generator 107 and the plane of incidence (e.g., the plane of FIG. 1) at an initial time (t=0), and spectral signals, α and β, are values defined as follows:

α=[tan²Ψ−tan²(A−A₀)]/[tan²Ψ+tan²(A−A₀)] (2)

and

β=[2(tan Ψ)(cos Δ)(tan(A−A₀))]/[tan²Ψ+tan²(A−A₀)] (3)

where tan(Ψ) is the amplitude of the complex ratio of the p and s reflection coefficients of the sample and Δ is the phase of the complex ratio of the p and s reflection coefficients of the sample. The “p” component denotes the component of polarized radiation whose electrical field is in the plane of FIG. 1, and “s” denotes the component of polarized radiation whose electrical field is perpendicular to the plane of FIG. 1. A is the nominal analyzer angle (e.g., a measured value of the orientation angle supplied, for example, from the above-mentioned analyzer position sensor associated with polarization state analyzer 109). A₀ is the offset of the actual orientation angle of polarization state analyzer 109 from the reading “A” (e.g., due to mechanical misalignment, A₀ may be non-zero).

In general, the spectral response of a specimen to a measurement is calculated by the metrology system based on functions of spectrometer data, S, and a subset of system parameter values, P_{sys1}, as illustrated by equations (4) and (5).

αₘₑₐₛ=m(P_{sys1},S) (4)

βₘₑₐₛ=n(P_{sys1},S) (5)

The subset of system parameter values, P_{sys1}, are those system parameters needed to determine the spectral response of the specimen to the measurement performed by the metrology system.

For the embodiment described with reference to FIG. 1, the subset of system parameters, P_{sys1}, includes the machine parameters of equations (1)-(3). Values of αₘₑₐₛ and βₘₑₐₛ are determined based on a measurement of a particular specimen by metrology system 100 and a subset of system parameter values as described by equations (1)-(3).

In general, ellipsometry is an indirect method of measuring physical properties of the specimen under inspection. In most cases, the measured values (e.g., αₘₑₐₛ and βₘₑₐₛ) cannot be used to directly determine the physical properties of the specimen. The nominal measurement process consists of formulating a measurement model that estimates the measured values (e.g., αₘₑₐₛ and βₘₑₐₛ) for a given measurement scenario. The measurement model characterizes the interaction of the specimen with the measurement system. The measurement model includes a parameterization of the structure (e.g., film thicknesses, critical dimensions, etc.) and the machine (e.g., wavelengths, angles of incidence, polarization angles, etc.). As illustrated in equations (6) and (7), the measurement model includes parameters associated with the machine (P_{machine}) and the specimen (P_{specimen}).

α_{model}=f(P_{machine},P_{specimen}) (6)

β_{model}=g(P_{machine},P_{specimen}) (7)

Machine parameters are parameters used to characterize the metrology tool (e.g., ellipsometer 101), and may include some or all of the subset of system parameters described with reference to equations (4) and (5). Exemplary machine parameters include angle of incidence (AOI), analyzer angle (A₀), polarizer angle (P₀), illumination wavelength, numerical aperture (NA), etc. Specimen parameters are parameters used to characterize the specimen (e.g., specimen 112 including structures 114). For a thin film specimen, exemplary specimen parameters include refractive index, dielectric function tensor, nominal layer thickness of all layers, layer sequence, etc. For measurement purposes, the machine parameters are treated as known, fixed parameters and the specimen parameters are treated as unknown, floating parameters. The floating parameters are resolved by an iterative process (e.g., regression) that produces the best fit between theoretical predictions and experimental data. The unknown specimen parameters, P_{specimen}, are varied and the model output values (e.g., α_{model} and β_{model}) are calculated until a set of specimen parameter values are determined that results in a close match between the model output values and the experimentally measured values (e.g., αₘₑₐₛ and βₘₑₐₛ).

In a model based measurement application such as spectroscopic ellipsometry, a regression process (e.g., ordinary least squares regression) is employed to identify specimen parameter values that minimize the differences between the model output values and the experimentally measured values for a fixed set of machine parameter values.

Measurement consistency across multiple measurement applications and across multiple tools depends on properly calibrated sets of machine parameter values for each measurement system. The estimated values of one or more parameters of interest estimated by each of a fleet of target metrology tools should match the estimated values of the one or more parameters of interest measured by a reference metrology tool within a desired tolerance. This is referred to as tool-to-tool matching. System model parameters are optimized for each target metrology tool to achieve tool-to-tool matching.

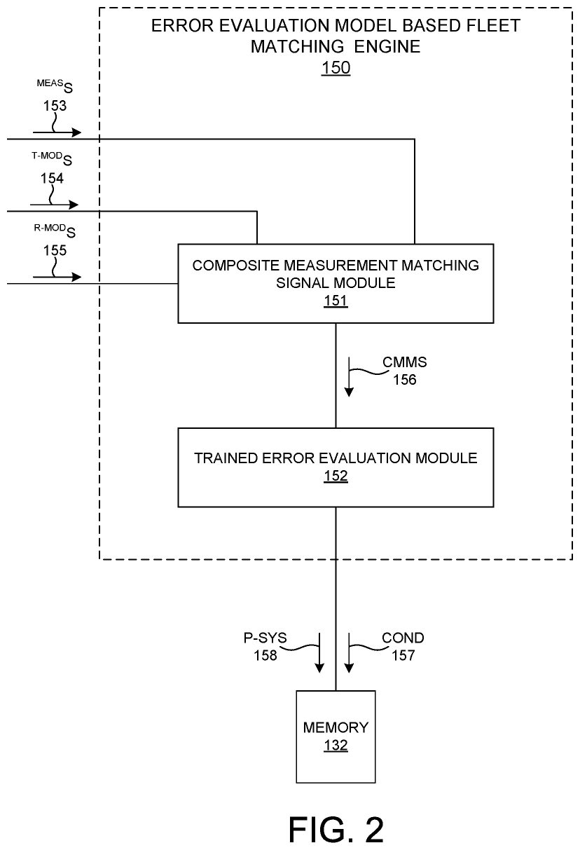

In one aspect, computing system 116 is configured as an error evaluation model based fleet matching engine 150 as illustrated in FIG. 2. Error evaluation model based fleet matching engine 150 employs a trained error evaluation model that enables systematic error monitoring and optimization across a fleet of metrology tools.

As depicted in FIG. 2, error evaluation model based fleet matching engine 150 includes a composite measurement matching signal module 151 and a trained error evaluation module 152. Composite measurement matching signal module 151 receives: 1) measurement signals, ^{MEAS}S 153, associated with the measurement of one or more metrology targets by a target measurement system; 2) model-based measurement signals, ^{T-MOD}S 154, associated with a model based simulation of measurement signals associated with the measurement of the one or more metrology targets by the target measurement system; and 3) model-based measurement signals, ^{R-MOD}S 155, associated with a model based simulation of measurement signals associated with a measurement of the one or more metrology targets by a reference measurement system. Composite measurement matching signal module 151 generates a composite measurement matching signal 156 based on ^{MEAS}S 153, ^{T-MOD}S 154, and ^{R-MOD}S 155. In general, composite measurement matching signal module 151 implements a mathematical function of ^{MEAS}S 153, ^{T-MOD}S 154, and ^{R-MOD}S 155, to generate CMMS 156. In one embodiment, the mathematical function is the sum of ^{MEAS}S 153 and the difference between ^{T-MOD}S 154, and ^{R-MOD}S 155 as illustrated by Equation (8).

CMMS=^{MEAS}S+(^{T-MOD}S−^{R-MOD}S) (8)

However, in general, composite measurement matching signal module 151 may implement any suitable mathematical function of ^{MEAS}S 154, ^{T-MOD}S 154, and ^{R-MOD}S 155 to generate CMMS 156.

As depicted in FIG. 2, CMMS 156 is communicated to trained error evaluation module 152. Trained error evaluation module 152 generates an indication of the matching condition of the target measurement system, COND 157, an indication of target system parameter values, P-SYS 158, or both. COND 157 is a signal indicative of whether the target measurement system employed to generate measurement signals, ^{MEAS}S 153, is matched to the reference measurement system within an acceptable tolerance. In some examples, condition signal, COND 157, is a binary signal, indicating that the target system is matched to the reference system within tolerance or not. In some other examples, condition signal, COND 157 is a numerical value that not only indicates whether or not the target measurement system is matched to the reference measurement system, but also the degree to which the target measurement system is matched to the reference measurement system.

P-SYS 158 is a signal indicative of target system parameter values to bring the match between the target measurement system and the reference measurement system within tolerance. In this example, the trained error evaluation model suggests system parameter values of the target measurement system that reduce the systematic errors of the target measurement system and match the target measurement system with the reference measurement system within an acceptable tolerance.

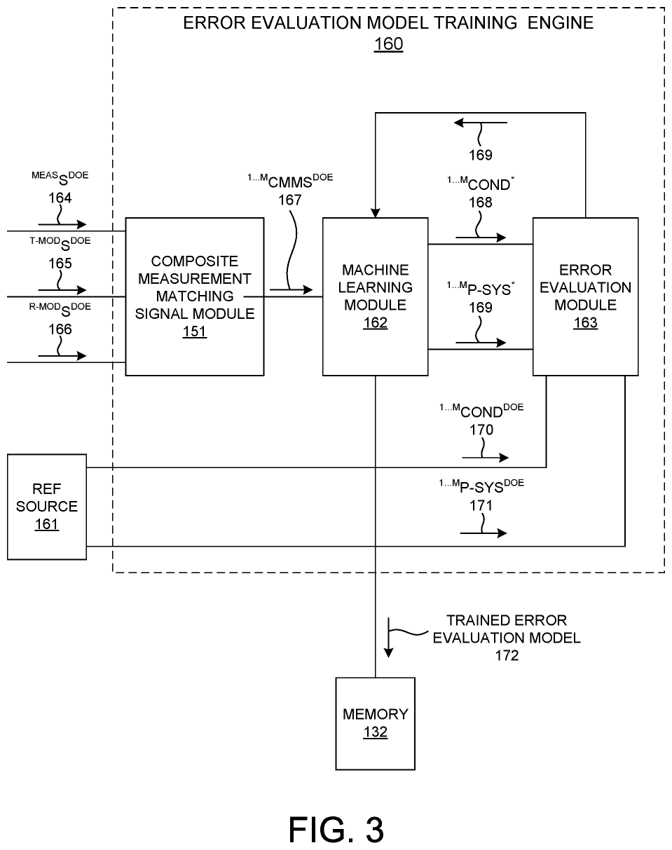

In a further aspect, computing system 116 is configured as an error evaluation model training engine 160 as illustrated in FIG. 3.

As depicted in FIG. 3, error evaluation model training engine 160 includes composite measurement matching signal module 151, as described with reference to FIG. 2, machine learning module 162, and error evaluation module 163. Composite measurement matching signal module 151 receives: 1) Design Of Experiments (DOE) measurement signals, ^{MEAS}S^{DOE} 164, associated with the measurement of one or more metrology targets by many target measurement systems; 2) DOE model-based target measurement signals, ^{T-MOD}S^{DOE} 165, associated with a model based simulation of measurement signals associated with each of the measurements of the one or more metrology targets by the target measurement systems; and 3) DOE model-based reference measurement signals, ^{R-MOD}S^{DOE} 166, associated with a model based simulation of measurement signals associated with measurements of the one or more metrology targets by a reference measurement system. Composite measurement matching signal module 151 generates a set of DOE composite measurement matching signals, ^{1 . . . M}CMMS^{DOE} 167, associated with each corresponding set of DOE measurement signals, DOE model-based target measurement signals, and DOE model-based reference measurement signals. In one example, the set of DOE composite measurement matching signals includes M different DOE measurements, where M is any positive, integer value. DOE composite measurement matching signals, ^{1 . . . M}CMMS^{DOE} 167, are communicated to machine learning module 162. Machine learning module 162 generates a current condition signal, ^{1 . . . M}COND* 168, indicative of whether the target measurement system associated with each of the M different DOE measurements is matched to the reference measurement system within an acceptable tolerance. Machine learning module 162 also generates a current system parameter signal, ^{1 . . . M}P-SYS* 169, indicative of current target system parameter values for the target measurement system associated with each of the M DOE measurements. Error evaluation module 163 receives the current condition signals and the current system parameter signals generated by machine learning module 162. In addition, error evaluation module 163 receives DOE condition signals, ^{1 . . . M}COND^{DOE} P-SYS^{DOE} 170 and DOE system parameter signals, ^{1 . . . M}P-SYS^{DOE} 171, associated with each of the M DOE measurements. The DOE condition signals and DOE system parameter signals are received from a reference signal source 161, e.g., a database of DOE measurement data. The DOE condition signals indicate the actual match between the target system and the reference system associated with each of the M DOE measurements. The DOE system parameter signals indicate the actual target system parameter values associated with each of the M DOE measurements. Error evaluation module 163 generates updated values of weighting parameters 169 of the error evaluation model 162 undergoing training to minimize differences between the DOE condition signals and the current condition signals and the DOE system parameter signals and the current system parameter signals. In the next iteration of model training, new current condition signals and new current system parameter signals are generated by machine learning module 162 based on the values of the weighting parameters 169 generated in the previous iteration. The training process continues until the differences between the DOE condition signals and the current condition signals and the DOE system parameter signals and the current system parameter signals are acceptably small. At this point, the trained error evaluation model 172 is stored in a memory, e.g., memory 132.

Although the error evaluation model training engine 160 describes training an error evaluation model suitable for evaluating fleet matching and compensating for systematic errors by determining system parameter values, in general, the error evaluation model training engine 160 may be configured to evaluate fleet matching only.

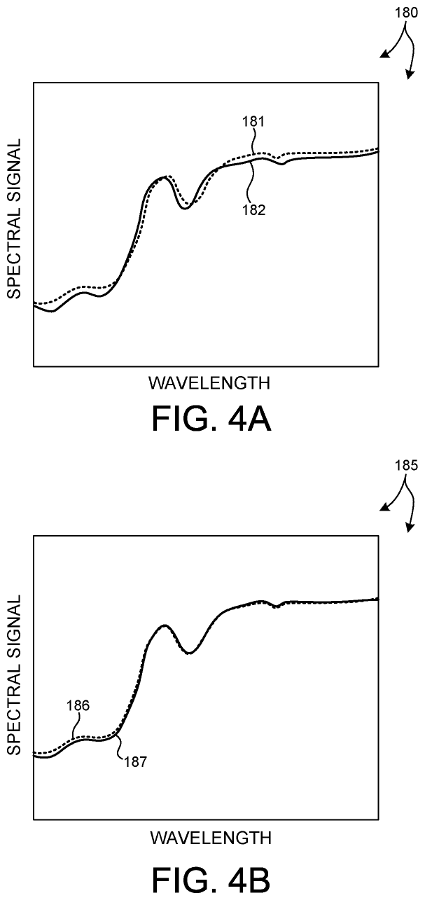

FIG. 4A-B illustrates matching of spectral measurement signals between a target metrology system and a reference metrology system over a range of illumination wavelengths before and after calibration of target system parameters using a trained error evaluation model.

FIG. 4A illustrates a plot 180 indicating spectral measurement signals associated with measurement of a metrology target as measured by a target metrology system and a reference metrology system over a range of illumination wavelengths before calibration of target system parameters. Plotline 181 illustrates a spectral measurement signal associated with a measurement of a metrology target as measured by a reference metrology system. Plotline 182 illustrates a spectral measurement signal associated with a measurement of the metrology target as measured by a target metrology system before calibration of target system parameters.

FIG. 4B illustrates a plot 185 indicating spectral measurement signals associated with measurement of the metrology target as measured by the target metrology system and the reference metrology system over a range of illumination wavelengths after calibration of target system parameters as described herein. Plotline 186 illustrates a spectral measurement signal associated with a measurement of the metrology target as measured by a reference metrology system. Plotline 187 illustrates a spectral measurement signal associated with a measurement of the metrology target as measured by the target metrology system after calibration of target system parameters. As depicted in FIGS. 4A-B, the match between the spectral signals measured by the reference and target metrology systems is much closer after calibration of the target system parameters as described herein.

As depicted in FIGS. 4A-B, calibration of system parameter values based on a trained error evaluation model results in significant improvements in tool-to-tool matching and measurement stability over a wide range of measurement applications.

The application of the aforementioned methods is not limited to a particular spectroscopic signal, i.e., the methods are applicable regardless of the spectroscopic signal under consideration, e.g., cos(A), tan(T), α and β harmonic signals, Mueller Matrix coefficient signals, etc. In one example, the indications of the measured spectral response are αₘₑₐₛ and βₘₑₐₛ values derived from measurement data by methods known in the art as discussed hereinbefore with reference to equations (1)-(5). In other examples, other indications of the measured spectral response may be contemplated (e.g., tan Ψ and Δ, etc.). The aforementioned spectral response indications are provided by way of non-limiting example. Other indications or combinations of indications may be contemplated. It is important to note that a spectral indication is based on the spectral response of the specimen, not specific metrics (e.g., film thickness, index of refraction, dielectric constants, etc.) that may be derived from the spectral response of the specimen.

Furthermore, the application of the aforementioned methods is not limited to a particular range of measured wavelengths, i.e., the methods are application regardless of the range of measured wavelengths, e.g., range including any of VUV, UV, visible, near-infrared, and mid-infrared wavelengths.

It should be further noted that the application of the aforementioned methods is not limited to spectroscopic ellipsometry. In general, the methods and systems for system parameter calibration may be applied to improve tool-to-tool matching and measurement stability of any measurement tool, in both on-line or off-line implementations. Such systems are employed to measure structural and material characteristics (e.g., material composition, dimensional characteristics of structures and films, etc.) associated with different semiconductor fabrication processes.

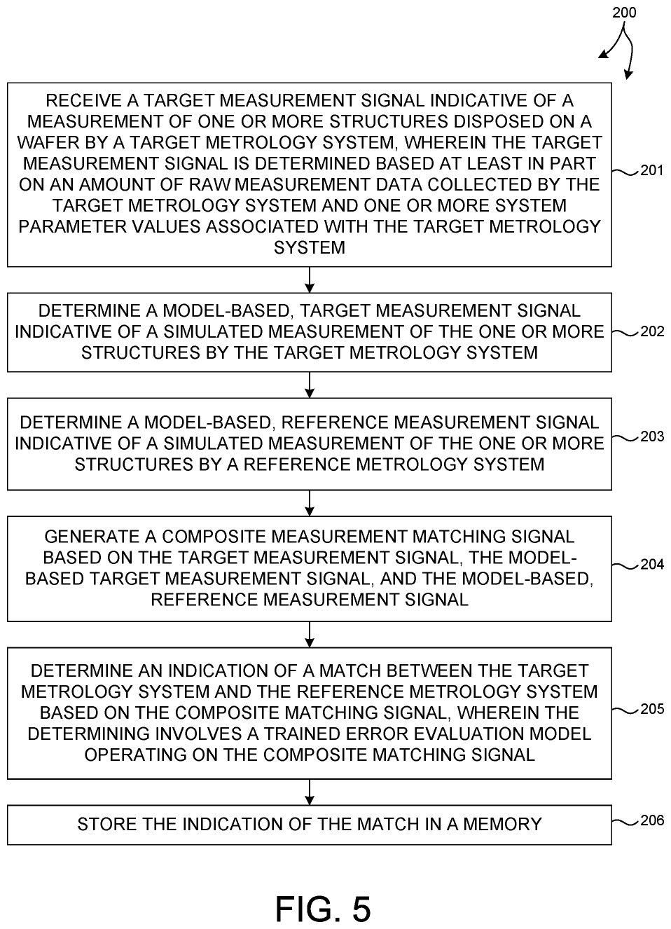

FIG. 5 illustrates a method 200 suitable for implementation by the metrology system 100 of the present invention. In one aspect, it is recognized that data processing blocks of method 200 may be carried out via a pre-programmed algorithm executed by one or more processors of computing system 116. While the following description is presented in the context of metrology system 100, it is recognized herein that the particular structural aspects of metrology system 100 do not represent limitations and should be interpreted as illustrative only.

In block 201, a target measurement signal is received by a computing system, e.g., computing system 116. The target measurement signal is indicative of a measurement of one or more structures disposed on a wafer by a target metrology system, e.g., metrology system 100. The target measurement signal is determined based at least in part on an amount of raw measurement data collected by the target metrology system and one or more system parameter values associated with the target metrology system.

In block 202, a model-based, target measurement signal indicative of a simulated measurement of the one or more structures by the target metrology system is determined.

In block 203, a model-based, reference measurement signal indicative of a simulated measurement of the one or more structures by a reference metrology system is determined.

In block 204, a composite measurement matching signal is generated based on the target measurement signal, the model-based target measurement signal, and the model-based, reference measurement signal.

In block 205, an indication of a match between the target metrology system and the reference metrology system is determined based on the composite matching signal. The determining involves a trained error evaluation model operating on the composite matching signal.

In block 206, the indication of the match is stored in a memory, e.g. a memory of carrier medium 118.

The terms reference metrology system and target metrology system generally refer to a metrology system status (i.e., target) that requires adaptation of the system parameters to obtain measurement consistency with another metrology system status (i.e., reference). In this manner, the target is being calibrated with respect to the reference.

In some examples, the target metrology system and the reference metrology system are different tools. For example, in a manufacturing context, it may be advantageous to have a fleet of metrology systems each calibrated to a single reference metrology system. In this manner, each of the fleet of metrology systems is consistent with a single reference tool. In another example, it may be advantageous to have a one or more metrology systems each calibrated to a fleet average of many metrology systems. In this manner, each of the metrology systems is consistent with an entire fleet of metrology tools. In another example, reference and target systems are the same system measured at different times (e.g., before and after a hardware maintenance operation).

In general, any suitable metrology system may be employed as the trusted metrology system within the scope of this patent document. For example, any of a beam profile reflectometer, a reflectometer, and an appropriate x-ray based metrology system may be employed as a trusted metrology system. In addition, there is no requirement that the trusted metrology system be integrated with the target metrology tool. In some examples, the trusted metrology system may be a separate metrology tool.

In a further aspect, the optimized subset of system parameters is loaded onto the target metrology system. These optimized parameters are subsequently used for further measurement analyses involving the measurement model (e.g., measurement model described with reference to equations (6) and (7)). In some examples, critical dimension (CD) measurements are performed by the target measurement system using the optimized subset of system parameters. For example, a structural parameter of the calibration specimen may be estimated based on a regression of the updated target system measurement model on the spectral data associated with the measurement of the calibration specimen. In this example, the spectral data is also calculated based on the underlying raw measurement data and the optimized subset of system parameters.

In another further aspect, the composite measurement matching signals driving the training of the error evaluation model can be weighted differently. In one example, the relative weightings are based on measurement sensitivity to any of multiple measurement sites, multiple measurement samples, multiple illumination wavelengths, and multiple measurement subsystems. In this manner, specific measurement sites, samples, subsystems, or illumination wavelengths with particularly high measurement sensitivity can be emphasized. In another example, the relative weightings are based on measurement noise associated any of multiple measurement sites, multiple measurement samples, multiple illumination wavelengths, and multiple measurement subsystems. In this manner, specific measurement sites, samples, subsystems, or illumination wavelengths with particularly high measurement noise can be de-emphasized.

Metrology systems configured to measure geometry and material properties of dielectric and metallic films and structures may employ the methods described herein. Such measurements include, by way of non-limiting example, film properties and dimensions, CD, overlay, and composition measurements. Such metrology systems may include any number of illumination sources, including, but not limited to lamps, lasers, laser driven sources, x-ray sources and EUV sources. Such metrology systems may employ an number of measurement technologies, including, but not limited to all implementations of ellipsometers (including broadband spectroscopic or single wavelength, single- or multi-angle, or angle-resolved, with fixed or rotating polarizers and compensators), all implementations of reflectometers (including spectroscopic or single wavelength, single- or multi-angle, or angle-resolved), all implementations of scatterometers, differential measurements, such as interferometers, and x-ray based metrologies.

As described herein, the term “metrology system” includes any system employed at least in part to characterize a specimen in any aspect. Exemplary terms used in the art may include a “defect inspection” system or an “inspection” system. However, such terms of art do not limit the scope of the term “metrology system” as described herein. In addition, the metrology system 100 may be configured for inspection of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the calibration of system parameters based on differences in error spectra between a reference and a target metrology tool.

Various embodiments are described herein for a semiconductor processing system (e.g., a metrology system or a lithography system) that may be used for processing a specimen. The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate.

One or more layers may be formed upon a wafer. For example, such layers may include, but are not limited to, a resist, a dielectric material, a conductive material, and a semiconductive material. Many different types of such layers are known in the art, and the term wafer as used herein is intended to encompass a wafer on which all types of such layers may be formed.

One or more layers formed on a wafer may be “patterned” or “unpatterned.” For example, a wafer may include a plurality of dies having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

A typical semiconductor process includes wafer processing by lot. As used herein a “lot” is a group of wafers (e.g., group of 25 wafers) which are processed together. Each wafer in the lot is comprised of many exposure fields from lithography processing tools (e.g. steppers, scanners, etc.). Within each field may exist multiple die. A die is the functional unit which eventually becomes a single chip. One or more layers formed on a wafer may be patterned or unpatterned. For example, a wafer may include a plurality of dies, each having repeatable patterned features. Formation and processing of such layers of material may ultimately result in completed devices. Many different types of devices may be formed on a wafer, and the term wafer as used herein is intended to encompass a wafer on which any type of device known in the art is being fabricated.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as quartz. A reticle may be disposed above a resist-covered wafer during an exposure step of a lithography process such that the pattern on the reticle may be transferred to the resist.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A method comprising:
receiving a target measurement signal indicative of a measurement of one or more structures disposed on a wafer by a target metrology system, wherein the target measurement signal is determined based at least in part on an amount of raw measurement data collected by the target metrology system and one or more system parameter values associated with the target metrology system;
determining a model-based, target measurement signal indicative of a simulated measurement of the one or more structures by the target metrology system;
determining a model-based, reference measurement signal indicative of a simulated measurement of the one or more structures by a reference metrology system;
generating a composite measurement matching signal based on the target measurement signal, the model-based target measurement signal, and the model-based, reference measurement signal;
determining an indication of a match between the target metrology system and the reference metrology system based on the composite matching signal, wherein the determining involves a trained error evaluation model operating on the composite matching signal; and
storing the indication of the match in a memory.

2. The method of claim 1, further comprising:
training the error evaluation model, wherein the training is based on Design Of Experiments (DOE) composite measurement matching signals associated with a plurality of DOE measurements of one or more structures by a fleet of metrology systems and corresponding indications of a match between each of the fleet of metrology systems and the reference metrology system.

3. The method of claim 1, further comprising:
determining a set of values of one or more system parameters of the target metrology system, wherein the determining involves the trained error evaluation model.

4. The method of claim 3, further comprising:
training the error evaluation model, wherein the training is based on Design Of Experiments (DOE) composite measurement matching signals associated with a plurality of DOE measurements of one or more structures by a fleet of metrology systems and corresponding indications of values of the one or more system parameters associated with each of the fleet of metrology systems.

5. The method of claim 1, wherein the composite measurement matching signal is a sum of the target measurement signal and a difference term, wherein the difference term is a difference between the model-based, reference measurement signal and the model-based, target measurement signal.

6. The method of claim 1, wherein the reference metrology system is a single metrology system of a fleet of metrology systems.

7. The method of claim 1, wherein the reference metrology system is an average of a plurality of metrology systems of the fleet of metrology systems.

8. The method of claim 1, wherein the target metrology system and the reference metrology system are spectroscopic ellipsometers.

9. The method of claim 1, wherein the reference metrology system is a metrology system measured at a first time and the target metrology system is the metrology system measured at a second time after the first time.

10. The method of claim 1, wherein the measurement of the one or more structures includes spectral measurement data associated with any of multiple measurement sites, multiple measurement samples, multiple illumination wavelengths, and multiple measurement modalities.

11. A metrology system, comprising:
an illumination source configured to provide an amount of illumination light to one or more metrology targets disposed on a wafer;
a detector configured to detect an amount of light from the one or more metrology targets in response to the amount of illumination light and generate measurement signals in response to the amount of detected light; and
one or more computing systems configured to:
receive a target measurement signal indicative of a measurement of one or more structures disposed on a wafer by a target metrology system, wherein the target measurement signal is determined based at least in part on an amount of raw measurement data collected by the target metrology system and one or more system parameter values associated with the target metrology system;
determine a model-based, target measurement signal indicative of a simulated measurement of the one or more structures by the target metrology system;
determine a model-based, reference measurement signal indicative of a simulated measurement of the one or more structures by a reference metrology system;
generate a composite measurement matching signal based on the target measurement signal, the model-based target measurement signal, and the model-based, reference measurement signal;
determine an indication of a match between the target metrology system and the reference metrology system based on the composite matching signal, wherein the determining involves a trained error evaluation model operating on the composite matching signal; and
store the indication of the match in a memory.

12. The metrology system of claim 11, the one or more computing systems further configured to:
train the error evaluation model, wherein the training is based on Design Of Experiments (DOE) composite measurement matching signals associated with a plurality of DOE measurements of one or more structures by a fleet of metrology systems and corresponding indications of a match between each of the fleet of metrology systems and the reference metrology system.

13. The metrology system of claim 11, the one or more computing systems further configured to:
determine a set of values of one or more system parameters of the target metrology system, wherein the determining involves the trained error evaluation model.

14. The metrology system of claim 13, further comprising:
training the error evaluation model, wherein the training is based on Design Of Experiments (DOE) composite measurement matching signals associated with a plurality of DOE measurements of one or more structures by a fleet of metrology systems and corresponding indications of values of the one or more system parameters associated with each of the fleet of metrology systems.

15. The metrology system of claim 11, wherein the composite measurement matching signal is a sum of the target measurement signal and a difference term, wherein the difference term is a difference between the model-based, reference measurement signal and the model-based, target measurement signal.

16. The metrology system of claim 11, wherein the reference metrology system is a single metrology system of a fleet of metrology systems.

17. The metrology system of claim 11, wherein the reference metrology system is an average of a plurality of metrology systems of the fleet of metrology systems.

18. The metrology system of claim 11, wherein the reference metrology system is a metrology system measured at a first time and the target metrology system is the metrology system measured at a second time after the first time.

19. A metrology system comprising:
an illumination source configured to provide an amount of illumination light to one or more metrology targets disposed on a wafer;
a detector configured to detect an amount of light from the one or more metrology targets in response to the amount of illumination light and generate measurement signals in response to the amount of detected light; and
a non-transient, computer-readable medium storing instructions that, when executed by one or more processors, causes the one or more processors to:
receive a target measurement signal indicative of a measurement of one or more structures disposed on a wafer by a target metrology system, wherein the target measurement signal is determined based at least in part on an amount of raw measurement data collected by the target metrology system and one or more system parameter values associated with the target metrology system;
determine a model-based, target measurement signal indicative of a simulated measurement of the one or more structures by the target metrology system;
determine a model-based, reference measurement signal indicative of a simulated measurement of the one or more structures by a reference metrology system;
generate a composite measurement matching signal based on the target measurement signal, the model-based target measurement signal, and the model-based, reference measurement signal;
determine an indication of a match between the target metrology system and the reference metrology system based on the composite matching signal, wherein the determining involves a trained error evaluation model operating on the composite matching signal; and
store the indication of the match in a memory.

20. The metrology system of claim 19, the non-transient, computer-readable medium further storing instructions that, when executed by the one or more processors, causes the one or more processors to:
determine a set of values of one or more system parameters of the target metrology system, wherein the determining involves the trained error evaluation model.
